(19) United States
(12) Patent Application Publication
(10) Pub. No.: US 2026/0113858 A1
(43) Pub. Date: Apr. 23, 2026

(54) Frequency Converter Kit

(71) Applicant: Lenze Swiss AG, Romanshorn (CH)

(72) Inventors: Karsten HUEBNER, Aerzen (DE); Erich SIDLER, Pfyn TG (CH); Daniel BOROWSKI, Guettingen (CH)

(21) Appl. No.: 18/868,331

(22) PCT Filed: May 25, 2023
(86) PCT No.: PCT/EP2023/064013

§ 371 Date: Jan. 9, 2026

(30) Foreign Application Priority Data
May 25, 2022 (DE) 10 2022 205 276.5

(51) Int. Cl. H05K 7/14; H05K 7/20

(52) U.S. Cl. CPC H05K 7/14324; H05K 7/209

(57) ABSTRACT

A frequency converter kit includes: basic units having a first plug-in connector by means of which the basic units are connectable to an AC voltage grid; a power electronics system; and a heat sink for cooling the power electronics system, wherein the heat sink has coupling elements; and extension units that are pluggable onto the basic units and have a port by means of which the extension units are connectable to the AC voltage grid; a first plug-in connector for forming a plug-in connection with the first plug-in connector of the basic units; and a housing element, the housing element having coupling elements. The coupling elements of the basic units and the coupling elements of the extension units are formed such that they interlock when the extension units are plugged onto the basic units.

### BACKGROUND AND SUMMARY

The invention relates to a frequency converter kit, and to a frequency converter formed from the frequency converter kit, which can be used as flexibly as possible, in particular with regard to their ports.

The frequency converter kit has basic units that have a basic functionality. A basic unit may serve, without any extension, as a frequency converter having a basic functional scope.

The basic units have a first, for example 3-, 4- or 5-pole, plug-in connector by means of which the basic units can be connected to an AC voltage grid, for example a three-phase AC voltage grid.

The basic units additionally have power electronics that are designed, for example, for conventional generation of control voltages for a three-phase motor. For this purpose, the power electronics may have, for example, a B6 bridge, etc.

The basic units additionally have a heat sink for cooling the power electronics. The heat sink may have, for example, outward-facing cooling fins that extend at an angle of, for example, 45 degrees in relation to a longitudinal axis of the basic units. The heat sink has a plurality of coupling elements, for example three.

The frequency converter kit additionally has extension units that can be plugged onto the basic unit.

The extension units have a terminal, for example a 3, 4 or 5-pin terminal, by means of which the extension units can be connected to the AC voltage grid.

The extension units have a first plug-in connector for forming a plug-in connection to the first plug-in connector of the basic units.

The extension units additionally have a housing element, wherein the housing element has a plurality of coupling elements, for example three.

The coupling elements of the basic units and the coupling elements of the extension units are shaped in such a way that they engage mutually when the extension units are plugged onto the basic units. The coupling elements of the basic units and the coupling elements of the extension units act in combination in such a way that they allow the extension units to be plugged onto the basic units only in a mutual alignment intended for this purpose. Further, following plugging-on, the coupling elements of the basic units and the coupling elements of the extension units mechanically fix the units to each other.

In one embodiment, the coupling elements of the basic units and the coupling elements of the extension units are shaped in such a way that they form a dovetail connection.

In one embodiment, the coupling elements of the basic units form pins, and the coupling elements of the extension units form correspondingly shaped, in particular trapezoidal, slots.

In one embodiment, the basic units have a second plug-in connector, wherein contacts of the second plug-in connector are electrically connected within the basic units to corresponding contacts of the first plug-in connector of the basic units in order to connect a plurality of frequency converters in a daisy-chain configuration to the AC voltage grid.

In one embodiment, the first plug-in connector of the basic units is female, and the second plug-in connector of the basic units is male.

In one embodiment, the extension units have an operating switch, for example a rotatable operating switch, wherein, when the operating switch is in a first switch position, the terminal of the extension units is electrically connected to the first plug-in connector of the extension units in order to connect a plugged-on basic unit to the AC voltage grid, and wherein, when the operating switch is in a second switch position, the terminal of the extension units is electrically disconnected from the first plug-in connector of the extension units in order to disconnect the plugged-on basic unit from the AC voltage grid.

In one embodiment, the extension units have a second plug-in connector, wherein contacts of the second plug-in connector are electrically connected within the extension units to corresponding contacts of the terminal of the extension units in order to connect a plurality of frequency converters in a daisy-chain configuration to the AC voltage grid.

In one embodiment, the terminal of the extension units is realized as a female plug-in connector, and the second plug-in connector of the extension units is male.

In one embodiment, the frequency converter kit has different types of extension units that differ in the type of their terminal. A first type of extension unit may have, for example, a terminal in the form of a plug-in connector, and a second type of extension unit may have, for example, a terminal in the form of a conventional spring-loaded terminal or screw terminal.

A frequency converter according to the invention is composed either of only a basic unit or of a basic unit and an extension unit.

The invention is described in detail below with reference to the drawings.

### BRIEF DESCRIPTION OF THE DRAWINGS

FIG. 1 is a perspective representation of a frequency converter kit that, as an example, comprises a basic unit and an extension unit;

FIG. 2 is a perspective representation of a basic unit;

FIG. 3 is a perspective representation of an opened basic unit; and

FIG. 4 is a perspective representation of an extension unit.

### DETAILED DESCRIPTION OF THE DRAWINGS

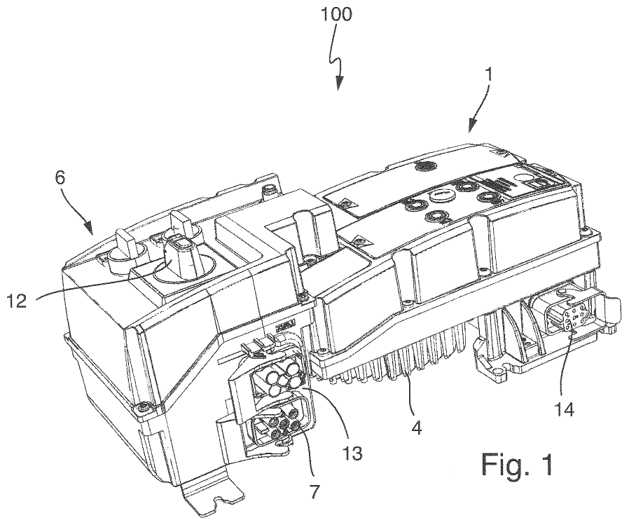

FIG. 1 shows a perspective representation of a frequency converter kit 100 that, as an example, comprises a basic unit 1 and an extension unit 6 that is plugged onto the basic unit 1. For reasons of visualization, only a single basic unit 1 and a single extension unit 6 are represented. It is understood that the frequency converter kit 100 may include more than the units 1 and 6 represented.

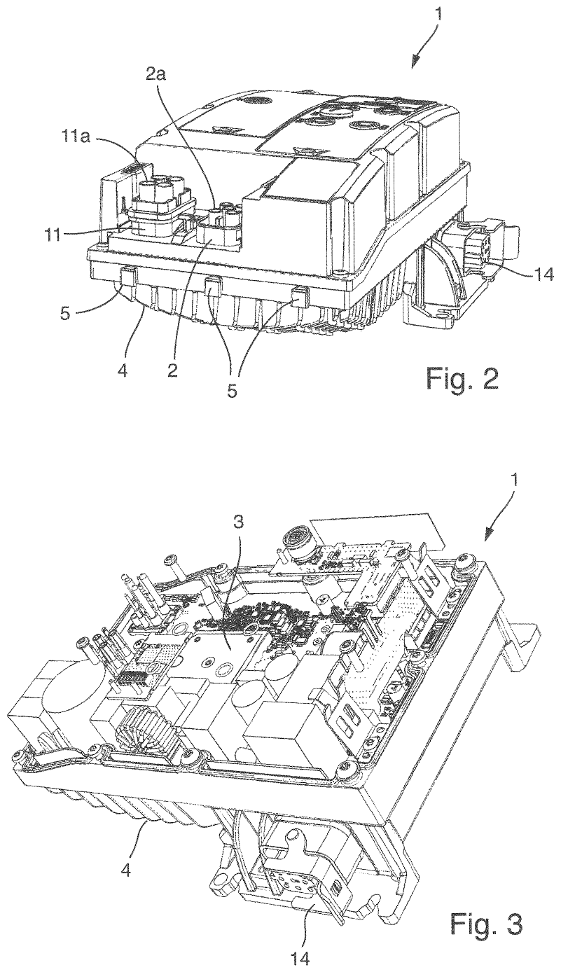

FIG. 2 shows a perspective representation of a basic unit 1, and FIG. 3 shows a perspective representation of an opened basic unit 1.

With reference to FIGS. 2 and 3, the basic unit 1 has a first plug-in connector 2, by means of which the basic unit 1 can be connected to a three-phase AC voltage grid. Further, the basic unit 1 has a second plug-in connector 11, with contacts 11a of the second plug-in connector 11 being electrically connected within the basic unit 1 to corresponding contacts 2a of the first plug-in connector 2 of the basic unit 1. The first plug-in connector 2 of the basic unit 1 is female, and the second plug-in connector 11 of the basic unit 1 is male. By means of the plug-in connectors 2 and 11, a plurality of basic units 1 may be connected in a daisy-chain configuration to the AC voltage grid.

The basic unit 1 has power electronics 3, and has a heat sink 4 for cooling the power electronics 3, the heat sink 4 having coupling elements 5, the function of which is described below.

The basic unit has a plug-in connector 14 for connecting a three-phase electric motor.

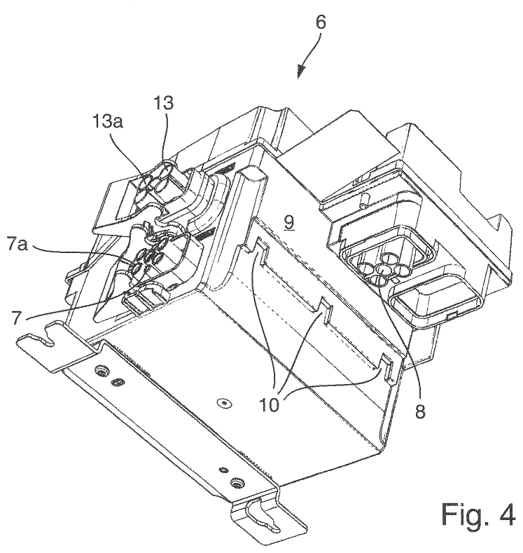

FIG. 4 shows a perspective representation of the extension unit 6. The extension unit 6 has a terminal 7 in the form of a female plug-in connector, by means of which the extension unit 6 can be connected to the AC voltage grid.

The extension unit 6 additionally has a first plug-in connector 8 for forming a plug-in connection to the first plug-in connector 2 of the basic unit 1.

The extension unit 6 additionally has a second plug-in connector 13, with contacts 13a of the second plug-in connector 13 being electrically connected within the extension unit 6 to corresponding contacts 7a of the terminal 7, or of the plug-in connector of the extension unit 6.

The terminal 7 of the extension unit 8 is realized as a female plug-in connector, and the second plug-in connector 13 of the extension units 6 is male.

The extension unit 6 additionally has a housing element 9, the housing element 9 having coupling elements 10. The coupling elements 5 of the basic unit 1 and the coupling elements 10 of the extension unit 6 are shaped in such a way that they engage mutually when the extension unit 6 is plugged onto the basic unit 1.

The coupling elements 5 of the basic unit 1 and the coupling elements 10 of the extension unit 6 are shaped in such a way that, in the process of plugging-on, they form a dovetail guide and, following the process of plugging-on, form a dovetail connection fitting. The coupling elements 5 of the basic unit 1 form pins, and the coupling elements 10 of the extension unit 6 form correspondingly shaped, trapezoidal slots.

With reference to FIG. 1, the extension unit 6 has an operating switch 12 and, when the operating switch 12 is in a first switch position, the plug-in connectors 7 and 13 of the extension unit 6 are electrically connected to the first plug-in connector 8 of the extension unit 6, such that the basic unit 1 is connected to the AC voltage grid.

When the operating switch 12 is in a second switch position, the plug-in connectors 7 and 13 of the extension unit 6 are electrically disconnected from the first plug-in connector 8 of the extension unit 6.

The frequency converter kit 100 may have different types of extension units 6 that differ, for example, in the type of their terminal 7 and/or 13.

If a basic functional scope is sufficient, the frequency converters are composed only of a basic unit 1. If an extended functional scope is required, the frequency converters are composed of a basic unit 1 and an extension unit 6.

1.-10. (canceled)

11. A frequency converter kit, comprising:
basic units, comprising:
a first plug-in connector, by which the basic units are connectable to an AC voltage grid,
power electronics, and
a heat sink for cooling the power electronics, wherein the heat sink has coupling elements;
extension units that are pluggable onto the basic units, the extension units comprising:
a port, by which the extension units are connected to the AC voltage grid,
a first plug-in connector for forming a plug-in connection to the first plug-in connector of the basic units, and
a housing element, wherein the housing element has coupling elements,
wherein the coupling elements of the basic units and the coupling elements of the extension units are shaped so as to be engage mutually when the extension units are plugged onto the basic units.

12. The frequency converter kit according to claim 11, wherein
the coupling elements of the basic units and the coupling elements of the extension units are shaped so as to form a dovetail connection.

13. The frequency converter kit according to claim 11, wherein
the coupling elements of the basic units form pins, and
the coupling elements of the extension units form correspondingly shaped slots.

14. The frequency converter kit according to claim 11, wherein
the basic units have a second plug-in connector, wherein contacts of the second plug-in connector are electrically connected within the basic units to corresponding contacts of the first plug-in connector of the basic units.

15. The frequency converter kit according to claim 14, wherein
the first plug-in connector of the basic units is female, and the second plug-in connector of the basic units is male.

16. The frequency converter kit according to claim 11, wherein
the extension units have an operating switch,
wherein, when the operating switch is in a first switch position, the port of the extension units is electrically connected to the first plug-in connector of the extension units, and
wherein, when the operating switch is in a second switch position, the port of the extension units is electrically disconnected from the first plug-in connector of the extension units.

17. The frequency converter kit according to claim 11, wherein
the extension units have a second plug-in connector, wherein contacts of the second plug-in connector are electrically connected within the extension units to corresponding contacts of the port of the extension units.

18. The frequency converter kit according to claim 17, wherein
the port of the extension units is realized as a female plug-in connector, and the second plug-in connector of the extension units is male.

19. The frequency converter kit according to claim 11, wherein
the frequency converter kit has different types of extension units that differ in a type of their port.

20. A frequency converter, comprising:
a basic unit and an extension unit of a frequency converter kit according to claim 11.
